(19) United States
(12) Patent Application Publication
(10) Pub. No.: US 2007/0134905 A1
(43) Pub. Date: Jun. 14, 2007

(54) Method for mounting bumps on an under metallurgy layer

(76) Inventors: Chi-Long Tsai, Kaohsiung (TW); Wan-Huei Lu, Kaohsiung (TW)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/637,794

(22) Filed: Dec. 13, 2006

(30) Foreign Application Priority Data
Dec. 14, 2005 (TW) 094144269

(51) Int. Cl. H01L 21/44

(52) U.S. Cl. 438/613; 257/E23.02

(57) ABSTRACT

The present invention relates to a method for mounting bumps on an under bump metallurgy layer (UBM layer). The method comprises (a) providing a wafer, having a plurality of solder pads and a protection layer, and the protection layer covering a surface of the wafer and exposing parts of the solder pads; (b) forming a first UBM layer on the solder pads and the protection layer; (c) forming a first photo resist on the first UBM layer, the first photo resist having a plurality of first openings corresponding to the exposing parts of the solder pads; (d) forming a second under bump metallurgy layer in the opening of the first photo resist; (e) forming a second photo resist on the first photo resist, the second photo resist having a plurality of second openings corresponding to the first openings of the first photo resist; (f)plating a solder layer in the first openings of the first photo resist and in the second openings of the second photo resist; (g) removing the second photo resist; (h) heating the solder layer to be a ball-shaped bump; (i) removing the first photo resist; and (j) removing part of the first UMB layer. Therefore, the UMB layer will not be reacted with bump in a reflow process and the problem of stress concentration will be avoided so as to make the bump more stable.

### BACKGROUND OF THE INVENTION

1. Field of the Invention

The invention relates to a method for mounting bumps, particularly to a method for mounting bumps on an under bump metallurgy layer.

2. Description of the Related Art

FIGS. 1A to 1F show a conventional method for mounting bumps on an under bump metallurgy layer. Firstly, referring to FIG. 1A, a wafer 10 is provided. The wafer 10 has an active surface 101, and the active surface 101 has a plurality of solder pads 103. A protection layer 102 covers the active surface 101. The protection layer 102 has a plurality of openings 104, wherein the openings 104 correspond to the solder pads 103 so as to expose parts of the solder pads 103. Referring to FIG. 1B, an under bump metallurgy layer 11 (UBM layer) is formed on the protection layer 102 and the solder pads 103. The under bump metallurgy layer 11 comprises an adhesion layer 111, a stress buffer layer 112 and a wetting layer 113. The solder pads 103 electrically connect to the under bump metallurgy layer 11.

A photo resist 12 is formed on the adhesion layer 111. The photo resist 12 has a plurality of openings 121, and the openings 121 are formed on the under bump metallurgy layer 11 and correspond to the solder pads 103. Referring to FIG. 1C, a solder paste 13 is filled into the openings 121 of the photo resist 12. Referring to FIG. 1D, the photo resist 12 is then removed. Referring to FIG. 1E, the adhesion layer 111 is etched so that the adhesion layer 111, the stress buffer layer 112 and the wetting layer 113 are of the same width. Referring to FIG. 1F, the solder paste 13 is heated to form a bump 14.

According to the conventional method for mounting bumps on under bump metallurgy layer, since the size of the adhesion layer 111 is the same as that of the stress buffer layer 112 and the wetting layer 113, the molten solder paste 13 flows down to the lateral of stress buffer layer 112 in a reflow process. Therefore, the problem of stress concentration will occur so that the bump 14 is unstable and peels easily due to the IMC (Intermetallic Compounds) formed between the bump 14 and stress buffer layer 112.

Consequently, there is an existing need for providing a method for mounting bumps on an under bump metallurgy layer to solve the above-mentioned problems.

### SUMMARY OF THE INVENTION

One objective of the present invention is to provide a method for mounting bumps on an under bump metallurgy layer (UBM layer). The method comprises (a) providing a wafer, having a plurality of solder pads and a protection layer, and the protection layer covering a surface of the wafer and exposing parts of the solder pads; (b) forming a first under bump metallurgy layer on the solder pads and the protection layer; (c) forming a first photo resist on the first under bump metallurgy layer, the first photo resist having a plurality of first openings corresponding to the exposing parts of the solder pads; (d) forming a second under bump metallurgy layer in the opening of the first photo resist; (e) forming a second photo resist on the first photo resist, the second photo resist having a plurality of second openings corresponding to the first openings of the first photo resist; (f) plating a solder layer in the first openings of the first photo resist and in the second openings of the second photo resist; (g) removing the second photo resist; (h) heating the solder layer to be a ball-shaped bump; (i) removing the first photo resist; and (j) removing part of the first under bump metallurgy layer.

In the method for mounting bumps on the under bump metallurgy layer of the present invention, since part of the first photo resist is formed on the first under bump metallurgy layer 211 and encircles the under bump metallurgy layer, the UMB layer will not be reacted with bump in a reflow process and the problem of stress concentration will be avoided so as to make the bump more stable.

### BRIEF DESCRIPTION OF THE DRAWINGS

FIGS. 1A to 1F show a conventional method for mounting bumps on an under bump metallurgy layer;

FIGS. 2A to 2G show a method for mounting bumps on an under bump metallurgy layer according to the present invention.

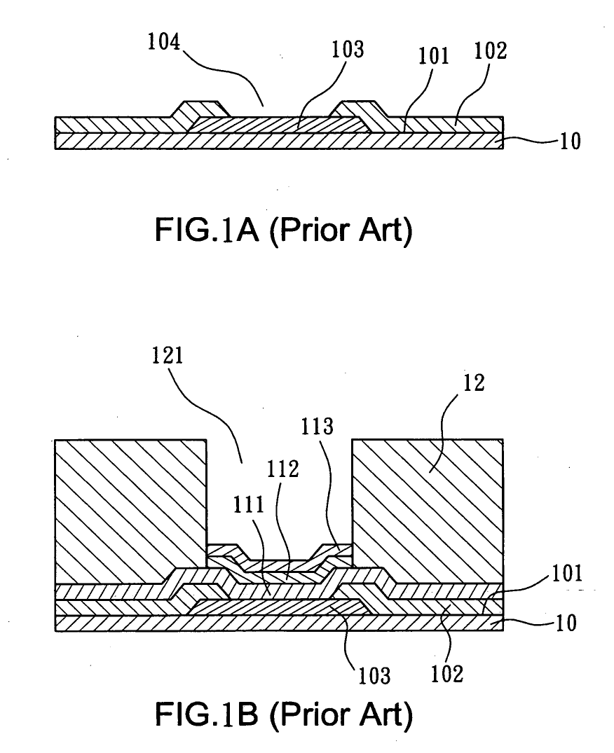

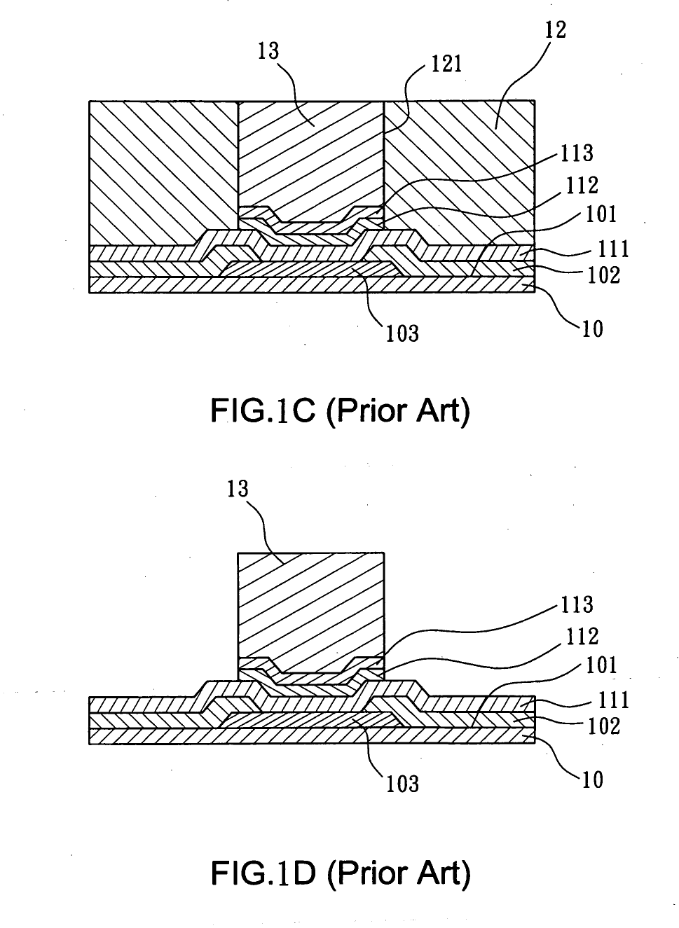

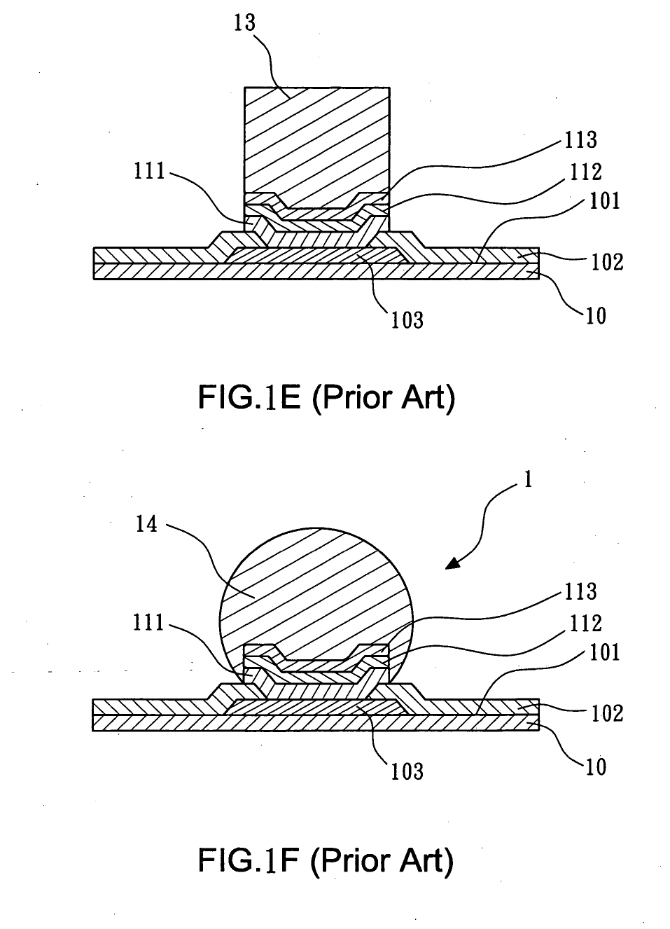

### DETAILED DESCRIPTION OF THE INVENTION

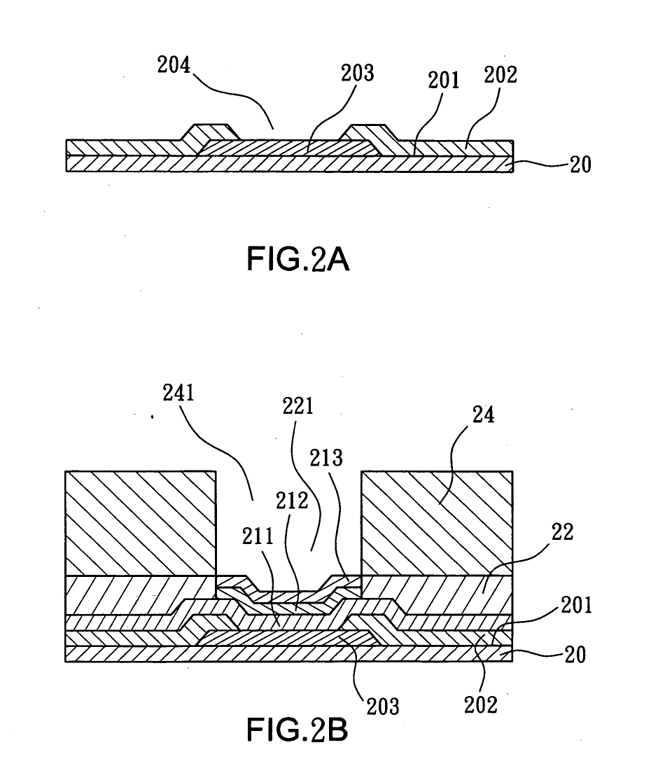

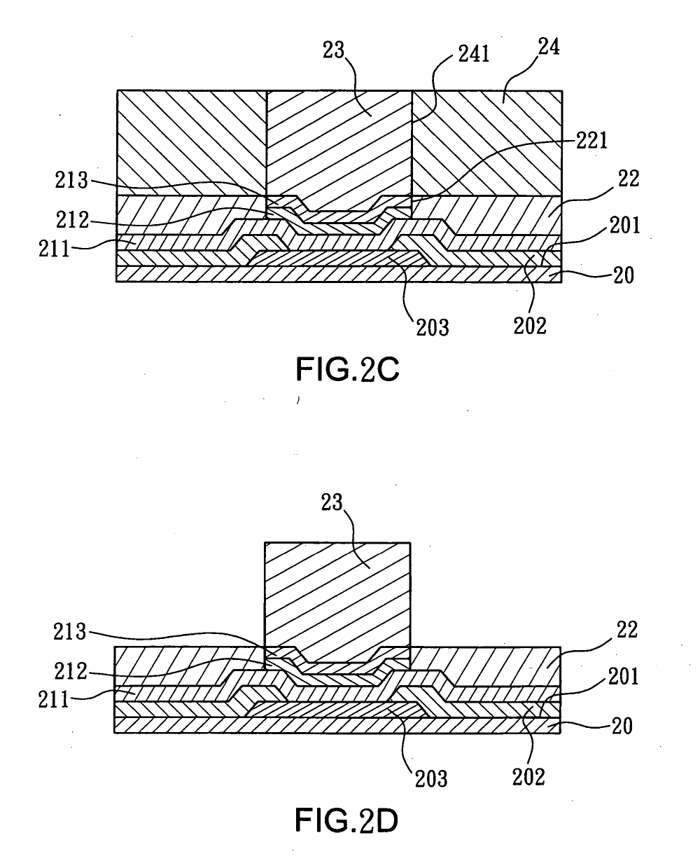

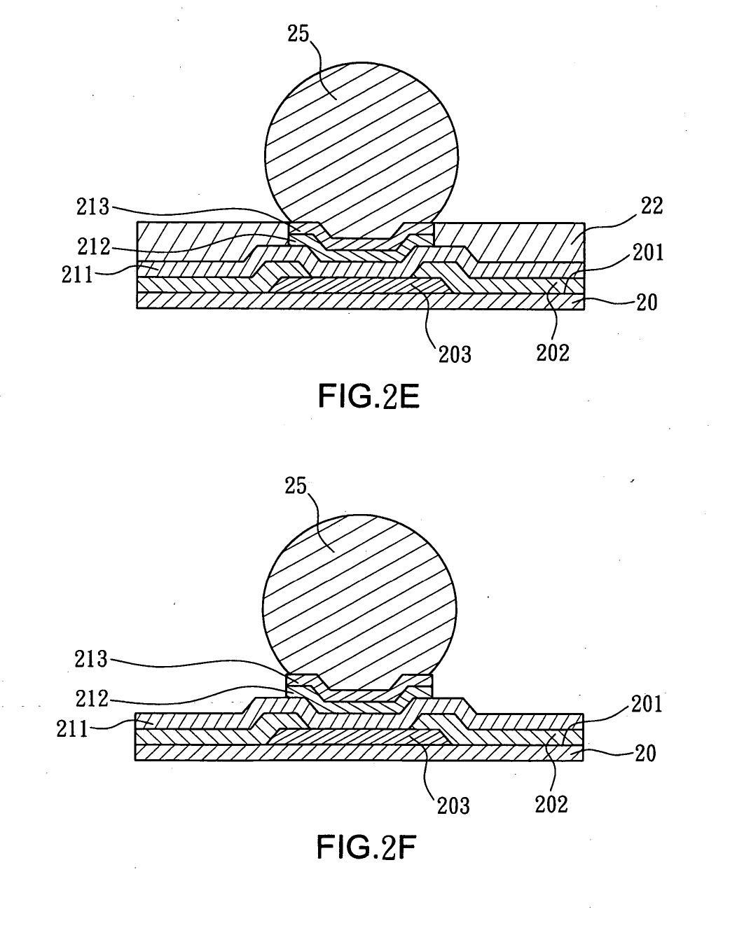

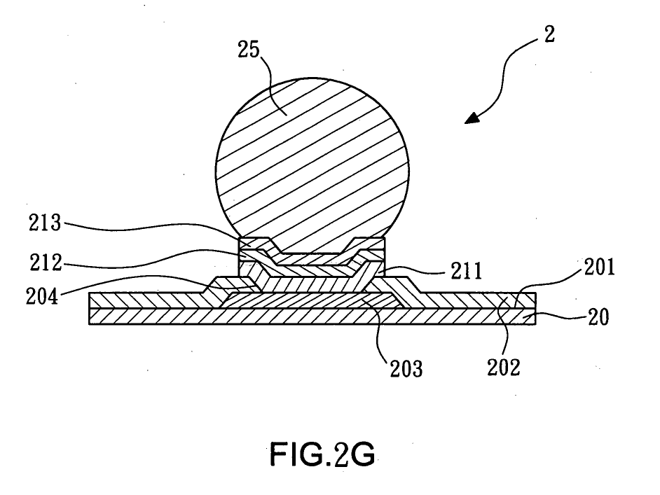

FIGS. 2A to 2G show a method for mounting bumps on an under bump metallurgy layer according to the present invention. Firstly, referring to FIG. 2A, a wafer 20 is provided. The wafer 20 has an active surface 201, and the active surface 201 has a plurality of solder pads 203. A protection layer 202 covers the active surface 201. The protection layer 202 has a plurality of openings 204, wherein the openings 204 correspond to the solder pads 203 so as to expose parts of the solder pads 203.

Referring to FIG. 2B, an under bump metallurgy layer 21 (UBM layer) is formed on the protection layer 202 and the solder pads 203. The under bump metallurgy layer 21 comprises a first under bump metallurgy layer 211 to be an adhesion layer, a second under bump metallurgy layer 212 to be a stress buffer layer and a third under bump metallurgy layer 213 to be a wetting layer, wherein the first under bump metallurgy layer 211 is formed by sputtering, and the second under bump metallurgy layer 212 and the third under bump metallurgy layer 213 are formed by plating. The solder pads 203 electrically connects to the under bump metallurgy layer 21.

In FIG. 2B, firstly, the first under bump metallurgy layer 211 is formed on the protection layer 202 and the solder pads 203. Then, a first photo resist 22 is formed on the first under bump metallurgy layer 21. A plurality of first openings 221 are formed by patterning the first photo resist 22. The first openings 221 are formed on the first under bump metallurgy layer 211, corresponding to the exposing parts of the solder pads 203. In the embodiment, the first photo resist 22 is a dry-film photo resist. In other application, the first photo resist 22 may be a liquid photo resist. The second under bump metallurgy layer 212 is formed in the opening 221 of the first photo resist 22. Furthermore, the third under bump metallurgy layer 213 is formed in the opening 221 of the first photo resist 22 after plating the second under bump metallurgy layer 212, and the step is optional. The first photo resist 22 is not lower than the third under bump metallurgy layer 213.

Finally, a second photo resist 24 is formed on the first photo resist 22. The second photo resist 24 has a plurality of second openings 241, corresponding to the first openings 221 of the first photo resist 22. It should be noted that the second photo resist 24 may be a dry-film photo resist or a liquid photo resist.

Referring to FIG. 2C, a solder layer 23 is plated in the first openings 221 of the first photo resist 22 and in the second openings 241 of the second photo resist 24. The solder layer 23 is a high-lead -solder material, for example 95/5, 97/3 or 90/10 solder material. Referring to FIG. 2D, the second photo resist 24 is removed. In the embodiment, the second photo resist 24 is removed by using exposure and development. Referring to FIG. 2E, the solder layer 23 is then heated so as to form as a ball-shaped bump 25.

Referring to FIG. 2F, the first photo resist 22 is removed. In the embodiment, the first photo resist 22 is removed by using exposure and development. Referring to FIG. 2G, part of the first under bump metallurgy layer 211 is removed. In the embodiment, an etching process proceeds so as to remove the part of the first under bump metallurgy layer 211, so that the first under bump metallurgy layer 211, the second under bump metallurgy layer 212 and the third under bump metallurgy layer 213 are of the same width.

According to the method for mounting bumps on the under bump metallurgy layer of the present invention, since the first photo resist 22 is formed on the first under bump metallurgy layer 211 and encircles the second under bump metallurgy layer 212 and the third under bump metallurgy layer 213, the under bump metallurgy layer 21 will not be reacted with the bump 25 in a reflow process and the problem of stress concentration will be avoided so as to make the bump 25 more stable.

While the embodiment of the present invention has been illustrated and described, various modifications and improvements can be made by those skilled in the art. The embodiments of the present invention are therefore described in an illustrative but not restrictive sense. It is intended that the present invention may not be limited to the particular forms as illustrated, and that all modifications that maintain the spirit and scope of the present invention are within the scope as defined in the appended claims.

What is claimed is:

1. A method for mounting bumps on an under bump metallurgy layer, the method comprising the following steps of:
(a) providing a wafer, having a plurality of solder pads and a protection layer, and the protection layer covering a surface of the wafer and exposing parts of the solder pads;
(b) forming a first under bump metallurgy layer (UBM layer) on the solder pads and the protection layer;
(c) forming a first photo resist on the first under bump metallurgy layer, the first photo resist having a plurality of first openings corresponding to the exposing parts of the solder pads;
(d) forming a second under bump metallurgy layer in the opening of the first photo resist;
(e) forming a second photo resist on the first photo resist, the second photo resist having a plurality of second openings corresponding to the first openings of the first photo resist;
(f) plating a solder layer in the first openings of the first photo resist and in the second openings of the second photo resist;
(g) removing the second photo resist;
(h) heating the solder layer so as to be a ball-shaped bump;
(i) removing the first photo resist; and
(j) removing part of the first under bump metallurgy layer.

2. The method according to claim 1, further comprising a step of forming a third under bump metallurgy layer in the opening of the first photo resist after forming the second under bump metallurgy layer in step (d).

3. The method according to claim 2, wherein the first under bump metallurgy layer comprises an adhesion layer, the second under bump metallurgy layer comprises a stress buffer layer and the third under bump metallurgy layer comprises a wetting layer.

4. The method according to claim 1, wherein the first under bump metallurgy layer is formed by sputtering.

5. The method according to claim 1, wherein the second under bump metallurgy layer is formed by plating.

6. The method according to claim 1, wherein the third under bump metallurgy layer is formed by plating.

7. The method according to claim 1, wherein the second photo resist is removed by using exposure and development in step (g).

8. The method according to claim 1, wherein part of the first photo resist is removed by using exposure and development ine step (i).

9. The method according to claim 1, wherein part of the first under bump metallurgy layer is removed by etching in step (j).

10. The method according to claim 1, wherein the first photo resist is a dry-film photo resist.

11. The method according to claim 1, wherein the first photo resist is a liquid photo resist.

12. The method according to claim 1, wherein the second photo resist is a dry-film photo resist.

13. The method according to claim 1, wherein the second photo resist is a liquid photo resist.
